(19) United States
(12) Patent Application Publication
(10) Pub. No.: US 2019/0296194 A1
(43) Pub. Date: Sep. 26, 2019

(54) METHOD FOR PRODUCING HERMETIC PACKAGE, AND HERMETIC PACKAGE

(71) Applicant: Nippon Electric Glass Co., Ltd., Shiga (JP)

(72) Inventors: Toru SHIRAGAMI, Shiga (JP); Takuji OKA, Shiga (JP)

(73) Assignee: Nippon Electric Glass Co., Ltd., Shiga (JP)

(21) Appl. No.: 16/305,964

(22) PCT Filed: Apr. 28, 2017
(86) PCT No.: PCT/JP2017/016975

§ 371 Date: Nov. 30, 2018

(30) Foreign Application Priority Data
Jun. 10, 2016 (JP) 2016-115837

(51) Int. Cl. H01L 33/48; H01L 21/52; H01L 23/10; H01L 23/053; C03C 25/6208

(52) U.S. Cl. CPC H01L 33/486; H01L 21/52; H01L 2933/0033; H01L 23/053; C03C 25/6208; H01L 23/10

(57) ABSTRACT

A method of producing a hermetic package of the present invention includes the steps of: preparing a ceramic base; preparing a glass cover; forming, on the glass cover, a sealing material layer having a total light transmittance in a thickness direction at a wavelength of laser light to be radiated of 10% or more and 80% or less; arranging the glass cover and the ceramic base so that the glass cover and the ceramic base are laminated on each other through intermediation of the sealing material layer; and irradiating the sealing material layer with the laser light from a glass cover side to soften and deform the sealing material layer, to thereby hermetically integrate the ceramic base and the glass cover with each other to obtain a hermetic package.

### TECHNICAL FIELD

The present invention relates to a method of producing a hermetic package, including hermetically sealing an aluminum nitride base and a glass cover with each other through sealing treatment using laser light (hereinafter referred to as “laser sealing”).

### BACKGROUND ART

In a hermetic package having mounted therein an ultraviolet LED device, aluminum nitride is used as a material for a base from the viewpoint of thermal conductivity, and glass is used as a material for a cover from the viewpoint of light transmissivity in an ultraviolet wavelength region.

An organic resin-based adhesive having a low-temperature curing property has hitherto been used as an adhesive material for an ultraviolet LED package. However, the organic resin-based adhesive is liable to be degraded with light in the ultraviolet wavelength region, and there is a risk in that the airtightness of the ultraviolet LED package may be reduced with time. In addition, when gold-tin solder is used instead of the organic resin-based adhesive, the degradation with light in the ultraviolet wavelength region can be prevented. However, the gold-tin solder has a problem of having high material cost.

Meanwhile, composite powder containing glass powder and refractory filler powder has the advantages of being less liable to be degraded with light in the ultraviolet wavelength region and having low material cost.

However, the glass powder has a higher softening temperature than the organic resin-based adhesive, and hence there is a risk in that the ultraviolet LED device may be thermally degraded at the time of sealing. Under such circumstances, laser sealing has attracted attention. According to the laser sealing, only a portion to be sealed can be locally heated, and an aluminum nitride base and a glass cover can be hermetically sealed with each other without thermal degradation of the ultraviolet LED device.

### CITATION LIST

Patent Literature 1: JP 2013-239609 A

Patent Literature 2: JP 2014-236202 A

### SUMMARY OF INVENTION

### Technical Problem

However, the related-art composite powder has the following problem: at the time of laser sealing, the composite powder is less susceptible to a reaction at an interface with a ceramic base, particularly an aluminum nitride base, and hence it becomes difficult to ensure sealing strength. Moreover, when the output of laser light is increased in order to increase the sealing strength, breakage, cracks, and the like are liable to occur in the glass cover or a sealing material layer. As the ceramic base has a higher thermal conductivity, the above-mentioned problem is more liable to manifest itself.

Thus, the present invention has been made in view of the above-mentioned circumstances, and a technical object of the present invention is to devise a method capable of ensuring high sealing strength at the time of laser sealing of a ceramic base and a glass cover without causing breakage, cracks, and the like in the glass cover and a sealing material layer, to thereby ensure hermetic reliability of a hermetic package.

### Solution to Problem

The inventors of the present invention have found the cause of difficulty in ensuring sealing strength at the time of laser sealing as described below. Specifically, a related-art sealing material has excessively high light absorption characteristics, and hence when a sealing material layer is irradiated with laser light from a glass cover side, a region of the sealing material layer on the glass cover side excessively absorbs the laser light. Meanwhile, the laser light which reaches a region of the sealing material layer on a ceramic base side tends to be deficient. Besides, a ceramic base has a high thermal conductivity, and hence draws heat from the sealing material layer. Therefore, through related-art laser sealing, the temperature in the region of the sealing material layer on the ceramic base side is not sufficiently increased and softening and deformation in the region become insufficient. As a result, it becomes difficult to form a reaction layer in a surface layer of the ceramic base. Consequently, it becomes difficult to ensure sealing strength.

Based on the above-mentioned finding, the inventors of the present invention have found that the above-mentioned technical object can be achieved by controlling the total light transmittance of the sealing material layer to fall within a predetermined range. Thus, the finding is proposed as the present invention. That is, according to one embodiment of the present invention, there is provided a method of producing a hermetic package, comprising the steps of: preparing a ceramic base; preparing a glass cover; forming, on the glass cover, a sealing material layer having a total light transmittance in a thickness direction at a wavelength of laser light to be radiated of 10% or more and 80% or less; arranging the glass cover and the ceramic base so that the glass cover and the ceramic base are laminated on each other through intermediation of the sealing material layer; and irradiating the sealing material layer with the laser light from a glass cover side to soften and deform the sealing material layer, to thereby hermetically integrate the ceramic base and the glass cover with each other to obtain a hermetic package. Herein, the “total light transmittance” may be measured with a commercially available transmittance measuring device. The “ceramic” includes glass ceramic (crystallized glass).

In the method of producing a hermetic package according to the embodiment of the present invention, the sealing material layer is formed not on the ceramic base but on the glass cover. This eliminates the need for firing of the ceramic base before laser sealing, and hence a light emitting device or the like can be housed in the ceramic base and electrical wiring or the like can be formed in the ceramic base before the laser sealing. As a result, the production efficiency of the hermetic package can be improved.

The method of producing a hermetic package according to the embodiment of the present invention comprises the step of forming, on the glass cover, a sealing material layer having a total light transmittance in a thickness direction at a wavelength of laser light to be radiated of 10% or more and 80% or less. With this, even when the output of the laser light is not excessively increased, the laser light is properly transmitted through a region of the sealing material layer on the glass cover side, and the laser light is properly absorbed into a region of the sealing material layer on a ceramic base side. As a result, the temperature of the sealing material layer is properly increased at an interface between the ceramic base and the sealing material layer at the time of laser sealing. In consequence, a reaction layer is formed in a surface layer of the ceramic base, and thus, the hermetic reliability of the hermetic package can be significantly improved. Further, the region of the sealing material layer on the glass cover side is not heated more than necessary, and hence a difference in temperature between members is reduced. Breakage, cracks, and the like caused by a difference in thermal expansion between the members are less liable to occur in the glass cover and the sealing material layer.

According to one embodiment of the present invention, there is provided a method of producing a hermetic package, comprising the steps of: preparing a ceramic base; preparing a glass cover; forming, on the glass cover, a sealing material layer having a total light transmittance in a thickness direction at a wavelength of 808 nm of 10% or more and 80% or less; arranging the glass cover and the ceramic base so that the glass cover and the ceramic base are laminated on each other through intermediation of the sealing material layer; and irradiating the sealing material layer with laser light from a glass cover side to soften and deform the sealing material layer, to thereby hermetically integrate the ceramic base and the glass cover with each other to obtain a hermetic package. The laser light to be used for laser sealing generally has a wavelength of from 600 nm to 1,600 nm. When a wavelength of 808 nm is adopted as a representative value in the above-mentioned wavelength region, and the total light transmittance of the sealing material layer in the thickness direction at a wavelength of 808 nm is controlled as described above, the above-mentioned effects can be appropriately exhibited.

Thirdly, in the method of producing a hermetic package according to the one embodiment of the present invention, the step of forming a sealing material layer is preferably performed so that the sealing material layer has an average thickness of less than 8.0 μm. With this, a difference in temperature between the region of the sealing material layer on the glass cover side and the region of the sealing material layer on the ceramic base side is reduced at the time of laser sealing. As a result, breakage, cracks, and the like caused by a difference in thermal expansion between the members are less liable to occur in the glass cover and the sealing material layer.

Fourthly, in the method of producing a hermetic package according to the one embodiment of the present invention, the step of forming a sealing material layer preferably comprises firing composite powder containing at least bismuth-based glass powder and refractory filler powder to form the sealing material layer on the glass cover. As compared to glasses based on other materials, the bismuth-based glass has the advantage of easily forming the reaction layer in the surface layer of the ceramic base at the time of laser sealing. In addition, the refractory filler powder can increase the mechanical strength of the sealing material layer while reducing the thermal expansion coefficient of the sealing material layer. The “bismuth-based glass” refers to glass comprising Bi₂O₃ as a main component, and specifically refers to glass comprising 25 mol % or more of Bi₂O₃ in a glass composition.

Fifthly, in the method of producing a hermetic package according to the one embodiment of the present invention, the ceramic base to used preferably comprises a base part and a frame part formed on the base part. With this, the light emitting device, such as an ultraviolet LED device, is easily housed in the hermetic package.

Sixthly, in the method of producing a hermetic package according to the one embodiment of the present invention, the ceramic base preferably has a property of absorbing the laser light to be radiated, that is, has a total light transmittance at the wavelength of the laser light to be radiated of 10% or less when having a thickness of 0.5 mm. With this, the temperature of the sealing material layer is easily increased at an interface between the ceramic base and the sealing material layer.

Seventhly, according to one embodiment of the present invention, there is provided a method of producing a hermetic package, comprising the steps of: preparing a ceramic base having dispersed therein a black pigment; preparing a glass cover; forming, on the glass cover, a sealing material layer having a total light transmittance in a thickness direction at a wavelength of laser light to be radiated of 10% or more and 80% or less; arranging the glass cover and the ceramic base so that the glass cover and the ceramic base are laminated on each other through intermediation of the sealing material layer; and irradiating the sealing material layer with the laser light from a glass cover side to soften and deform the sealing material layer and heat the ceramic base, to thereby hermetically integrate the ceramic base and the glass cover with each other to obtain a hermetic package.

Eighthly, according to one embodiment of the present invention, there is provided a hermetic package, comprising a ceramic base and a glass cover hermetically integrated with each other through intermediation of a sealing material layer, wherein the sealing material layer has a total light transmittance in a thickness direction at a wavelength of 808 nm of 10% or more and 80% or less.

Ninthly, in the hermetic package according to the one embodiment of the present invention, the sealing material layer preferably has an average thickness of less than 8.0 μm. With this, a stress remaining in the hermetic package is reduced, and hence the hermetic reliability of the hermetic package can be improved.

Tenthly, in the hermetic package according to the one embodiment of the present invention, the sealing material layer preferably comprises a sintered body of composite powder containing at least bismuth-based glass powder and refractory filler powder.

Eleventhly, in the hermetic package according to the one embodiment of the present invention, the sealing material layer is preferably substantially free of a laser absorber. Herein, the “substantially free of a laser absorber” refers to a case in which the content of the laser absorber in the sealing material layer is 0.1 vol % or less.

Twelfthly, in the hermetic package according to the one embodiment of the present invention, the ceramic base preferably comprises a base part and a frame part formed on the base part. With this, the light emitting device, such as an ultraviolet LED device, is easily housed in the hermetic package.

Thirteenthly, in the hermetic package according to the one embodiment of the present invention, the ceramic base preferably has a thermal conductivity of 1 W/(m·K) or more. When the ceramic base has a high thermal conductivity, the ceramic base is liable to dissipate heat, and hence it becomes difficult to increase the temperature of the sealing material layer at an interface between the ceramic base and the sealing material layer at the time of laser sealing. Therefore, as the ceramic base has a higher thermal conductivity, the effects of the present invention are relatively increased.

Fourteenthly, in the hermetic package according to the one embodiment of the present invention, the ceramic base preferably comprises any one of glass ceramic, aluminum nitride, and alumina, or a composite material thereof.

Fifteenthly, the hermetic package according to the one embodiment of the present invention preferably has housed therein an ultraviolet LED device. Herein, the “ultraviolet LED device” includes a deep ultraviolet LED device. Other than the above, the hermetic package may also have housed therein any one of a sensor device, a piezoelectric vibration device, and a wavelength conversion device in which quantum dots are dispersed in a resin.

### BRIEF DESCRIPTION OF DRAWINGS

FIG. 1 is a schematic view for illustrating a softening point of composite powder measured with a macro-type DTA apparatus.

FIG. 2 is a conceptual sectional view for illustrating an embodiment of the present invention.

### DESCRIPTION OF EMBODIMENTS

A method of producing a hermetic package of the present invention comprises a step of preparing a ceramic base. A sintered glass-containing layer may be formed on the ceramic base as required. With this, at the time of laser sealing, a situation in which bubbles are generated in a sealing material layer can be prevented, while sealing strength is increased. As a result, the hermetic reliability of a hermetic package can be improved. The sintered glass-containing layer may be preferably formed by a method involving applying a glass-containing paste onto the ceramic base to form a glass-containing film, followed by drying the glass-containing film to volatilize a solvent, and further, irradiating the glass-containing film with laser light to sinter (fix) the glass-containing film. When the glass-containing film is sintered through irradiation with laser light, the sintered glass-containing layer can be formed without causing thermal degradation of electrical wiring formed in the ceramic base or a light emitting device housed in the ceramic base. The sintered glass-containing layer may be formed through firing of the glass-containing film instead of the irradiation with laser light. In this case, in order to prevent the thermal degradation of the light emitting device or the like, the firing of the glass-containing film is preferably performed before the light emitting device or the like is mounted in the ceramic base.

The ceramic base has a thermal conductivity of preferably 1 W/(m·K) or more, 10 W/(m·K) or more, or 50 W/(m·K) or more, particularly preferably 100 W/(m·K) or more. When the ceramic base has a high thermal conductivity, the ceramic base is liable to dissipate heat, and hence it becomes difficult to increase the temperature of the sealing material layer at an interface between the ceramic base and the sealing material layer at the time of laser sealing. Therefore, as the ceramic base has a higher thermal conductivity, the effects of the present invention are relatively increased.

The ceramic base preferably has a property of absorbing laser light to be radiated, that is, has a total light transmittance at the wavelength of the laser light to be radiated of 10% or less (desirably 5% or less) when having a thickness of 0.5 mm. Similarly, the ceramic base preferably has a total light transmittance at a wavelength of 808 nm of 10% or less (desirably 5% or less) when having a thickness of 0.5 mm. With this, the temperature of the sealing material layer is easily increased at an interface between the ceramic base and the sealing material layer.

The ceramic base is preferably sintered under the state in which the ceramic base comprises a laser absorber (e.g., black pigment). With this, the property of absorbing laser light to be radiated can be imparted to the ceramic base.

The thickness of the ceramic base is preferably from 0.1 mm to 4.5 mm, particularly preferably from 0.5 mm to 3.0 mm. With this, thinning of the hermetic package can be achieved.

In addition, as the ceramic base, it is preferred to use a ceramic base comprising a base part and a frame part formed on the base part. With this, a light emitting device, such as an ultraviolet LED device, is easily housed within the frame part of the ceramic base. When the sintered glass-containing layer is formed on the ceramic base, the sintered glass-containing layer is preferably formed on a top of the frame part in order to prevent thermal degradation of the light emitting device or the like.

When the ceramic base comprises the frame part, it is preferred to form the frame part on the ceramic base along a peripheral end edge region thereof in a frame shape. With this, the effective area for functioning as a device can be enlarged. In addition, the light emitting device, such as an ultraviolet LED device, is easily housed inside the frame part of the ceramic base.

The ceramic base is preferably formed of any one of glass ceramic, aluminum nitride, and alumina, or a composite material thereof. In particular, aluminum nitride and alumina each have a satisfactory heat dissipating property, and hence a situation in which the hermetic package excessively generates heat owing to light radiated from a light emitting device, such as an ultraviolet LED device, can be properly prevented.

The ceramic base preferably has dispersed therein a black pigment (sintered under the state in which the ceramic base has dispersed therein a black pigment). With this, the ceramic base can absorb laser light having been transmitted through the sealing material layer. As a result, the ceramic base is heated at the time of laser sealing, and hence formation of a reaction layer at an interface between the sealing material layer and the ceramic base can be promoted.

The method of producing a hermetic package of the present invention comprises a step of preparing a glass cover, and forming, on the glass cover, a sealing material layer.

In the method of producing a hermetic package of the present invention, the total light transmittance of the sealing material layer in a thickness direction at the wavelength of the laser light to be radiated is 10% or more, preferably 15% or more or 20% or more, particularly preferably 25% or more. When the total light transmittance of the sealing material layer in the thickness direction at the wavelength of the laser light to be radiated is too low, a region of the sealing material layer on a glass cover side is softened and deformed preferentially when the sealing material layer is irradiated with the laser light from the glass cover side, and hence the laser light does not sufficiently reach a region of the sealing material layer on a ceramic base side. As a result, it becomes difficult to increase a temperature at an interface between the ceramic base and the sealing material layer, and it becomes difficult to form the reaction layer in a surface layer of the ceramic base. Meanwhile, the total light transmittance of the sealing material layer in the thickness direction at the wavelength of the laser light to be radiated is 80% or less, preferably 60% or less, 50% or less, or 45% or less, particularly preferably 40% or less. When the total light transmittance of the sealing material layer in the thickness direction at the wavelength of the laser light to be radiated is too high, the sealing material layer does not appropriately absorb the laser light even when the sealing material layer is irradiated with the laser light from the glass cover side. As a result, it becomes difficult to increase the temperature of the sealing material layer, and it becomes difficult to form the reaction layer in the surface layer of the ceramic base. As a method of increasing the total light transmittance of the sealing material layer in the thickness direction, the following methods are given: a method involving reducing the content of a laser absorber; and a method involving reducing the content of a laser absorbing component (e.g., CuO or Fe₂O₃) in a glass composition of glass powder.

In the method of producing a hermetic package of the present invention, the total light transmittance of the sealing material layer in the thickness direction at a wavelength of 808 nm is 10% or more, preferably 15% or more or 20% or more, particularly preferably 25% or more. When the total light transmittance of the sealing material layer in the thickness direction at a wavelength of 808 nm is too low, the region of the sealing material layer on the glass cover side is softened and deformed preferentially when the sealing material layer is irradiated with the laser light from the glass cover side. As a result, it becomes difficult to increase a temperature at an interface between the ceramic base and the sealing material layer, and it becomes difficult to form the reaction layer in the surface layer of the ceramic base. Meanwhile, the total light transmittance of the sealing material layer in the thickness direction at a wavelength of 808 nm is 80% or less, preferably 60% or less, 50% or less, or 45% or less, particularly preferably 40% or less. When the total light transmittance of the sealing material layer in the thickness direction at a wavelength of 808 nm is too high, the sealing material layer does not appropriately absorb the laser light even when the sealing material layer is irradiated with the laser light from the glass cover side. As a result, it becomes difficult to increase the temperature of the sealing material layer, and it becomes difficult to form the reaction layer in the surface layer of the ceramic base.

The average thickness of the sealing material layer before laser sealing is controlled to preferably less than 8.0 μm, particularly preferably less than 6.0 μm. Similarly, also the average thickness of the sealing material layer after the laser sealing is controlled to preferably less than 8.0 μm, particularly preferably less than 6.0 μm. As the average thickness of the sealing material layer is reduced more, a stress remaining in sealed sites after the laser sealing can be reduced more when the thermal expansion coefficient of the sealing material layer and the thermal expansion coefficient of the glass cover do not match each other. In addition, also the accuracy of the laser sealing can be improved more. As a method of controlling the average thickness of the sealing material layer as described above, the following methods are given: a method involving thinly applying a composite powder paste; and a method involving subjecting the surface of the sealing material layer to polishing treatment.

The surface roughness Ra of the sealing material layer is controlled to preferably less than 0.5 μm or 0.2 μm or less, particularly preferably from 0.01 μm to 0.15 μm. In addition, the surface roughness RMS of the sealing material layer is controlled to preferably less than 1.0 μm or 0.5 μm or less, particularly preferably from 0.05 μm to 0.3 μm. With this, the adhesiveness between the ceramic base and the sealing material layer is increased, and the accuracy of the laser sealing is improved. A method of controlling the surface roughnesses Ra and RMS of the sealing material layer as described above, the following methods are given: a method involving subjecting the surface of the sealing material layer to polishing treatment; and a method involving reducing the particle size of refractory filler powder. The “surface roughness Ra” and the “surface roughness RMS” may be measured with, for example, a contact-type or non-contact-type laser film thickness meter or surface roughness meter.

The line width of the sealing material layer is preferably 2,000 μm or less or 1,500 μm or less, particularly preferably 1,000 μm or less. When the line width of the sealing material layer is too large, a stress remaining in the hermetic package is liable to be increased.

At the time of laser sealing, the sealing material layer is softened and deformed to form the reaction layer in the surface layer of the ceramic base. The sealing material layer is preferably formed of a sintered body of composite powder containing at least glass powder and refractory filler powder. Various materials may be used as the composite powder. Of those, composite powder containing bismuth-based glass powder and refractory filler powder is preferably used from the viewpoint of increasing sealing strength. In particular, as the composite powder, it is preferred to use composite powder comprising 55 vol % to 95 vol % of bismuth-based glass and 5 vol % to 45 vol % of refractory filler powder. It is more preferred to use composite powder comprising 60 vol % to 85 vol % of bismuth-based glass and 15 vol % to 40 vol % of refractory filler powder. It is particularly preferred to use composite powder comprising 60 vol % to 80 vol % of bismuth-based glass and 20 vol % to 40 vol % of refractory filler powder. When the refractory filler powder is added, the thermal expansion coefficient of the sealing material layer easily matches the thermal expansion coefficients of the glass cover and the ceramic base. As a result, a situation in which an improper stress remains in the sealed sites after the laser sealing is prevented easily. Meanwhile, when the content of the refractory filler powder is too large, the content of the bismuth-based glass powder is relatively reduced. Thus, the surface smoothness of the sealing material layer is decreased, and the accuracy of the laser sealing is liable to be decreased.

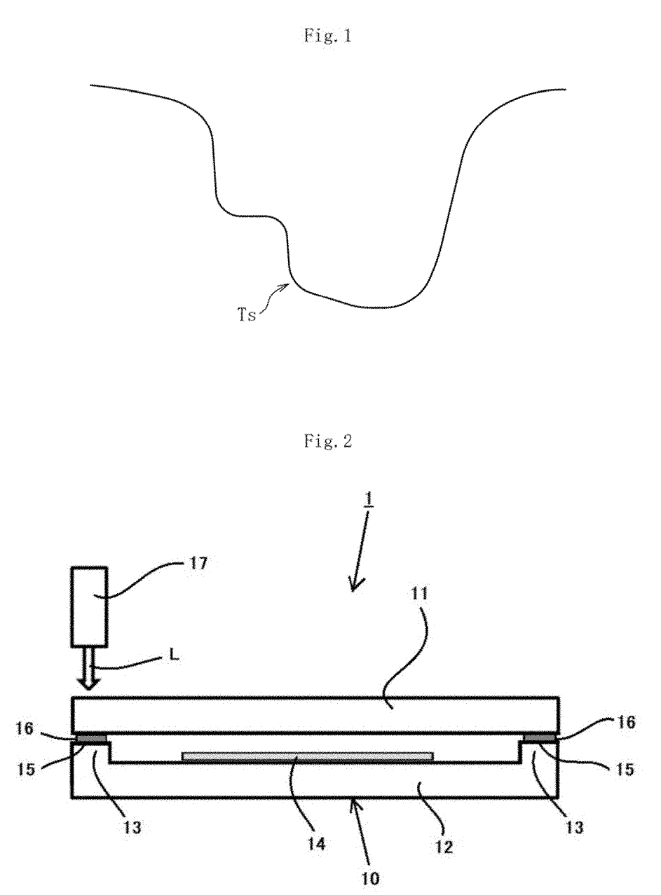

The softening point of the composite powder is preferably 500° C. or less or 480° C. or less, particularly preferably 450° C. or less. When the softening point of the composite powder is too high, it becomes difficult to increase the surface smoothness of the sealing material layer. The lower limit of the softening point of the composite powder is not particularly set, but in consideration of the thermal stability of the glass powder, the softening point of the composite powder is preferably 350° C. or more. Herein, the “softening point” refers to the fourth inflection point measured with a macro-type DTA apparatus, and corresponds to Ts in FIG. 1.

The bismuth-based glass preferably comprises as a glass composition, in terms of mol %, 28% to 60% of Bi₂O₃, 0.15% to 37% of B₂O₃, and 1% to 30% of ZnO. The reasons why the content range of each component is limited as described above are described below. In the description of the glass composition range, the expression “%” means “mol %”.

Bi₂O₃ is a main component for lowering a softening point, and the content of Bi₂O₃ is preferably from 28% to 60% or from 33% to 55%, particularly preferably from 35% to 45%. When the content of Bi₂O₃ is too small, the softening point becomes too high and hence flowability is liable to lower. Meanwhile, when the content of Bi₂O₃ is too large, the glass is liable to devitrify at the time of laser sealing, and owing to the devitrification, the flowability is liable to lower.

B₂O₃ is an essential component as a glass-forming component, and the content of B₂O₃ is preferably from 15% to 37% or from 19% to 33%, particularly preferably from 22% to 30%. When the content of B₂O₃ is too small, a glass network is hardly formed, and hence the glass is liable to devitrify at the time of laser sealing. Meanwhile, when the content of B₂O₃ is too large, the glass has an increased viscosity, and hence the flowability is liable to lower.

ZnO is a component which improves devitrification resistance, and the content of ZnO is preferably from 1% to 30%, from 3% to 25%, or from 5% to 22%, particularly preferably from 7% to 20%. When the content of ZnO is outside the above-mentioned range, the glass composition loses its component balance, and hence the devitrification resistance is liable to lower.

In addition to the above-mentioned components, for example, the following components may be added.

SiO₂ is a component which improves water resistance, and the content of SiO₂ is preferably from 0% to 5%, from 0% to 3%, or from 0% to 2%, particularly preferably from 0% to 1%. When the content of SiO₂ is too large, the softening point is inappropriately increased. In addition, the glass is liable to devitrify at the time of laser sealing.

Al₂O₃ is a component which improves the water resistance, and the content of Al₂O₃ is preferably from 0% to 10% or from 0.1% to 5%, particularly preferably from 0.5% to 3%. When the content of Al₂O₃ is too large, there is a risk in that the softening point is inappropriately increased.

Li₂O, Na₂O, and K₂O are each a component which reduces the devitrification resistance. Therefore, the content of each of Li₂O, Na₂O, and K₂O is from 0% to 5% or from 0% to 3%, particularly preferably from 0% to less than 1%.

MgO, CaO, SrO, and BaO are each a component which improves the devitrification resistance, but are each a component which increases the softening point. Therefore, the content of each of MgO, CaO, SrO, and BaO is from 0% to 20% or from 0% to 10%, particularly preferably from 0% to 5%.

In order to lower the softening point of bismuth-based glass, it is required to introduce a large amount of Bi₂O₃ into the glass composition, but when the content of Bi₂O₃ is increased, the glass is liable to devitrify at the time of laser sealing, and owing to the devitrification, the flowability is liable to lower. This tendency is particularly remarkable when the content of Bi₂O₃ is 30% or more. As a countermeasure for this problem, the addition of CuO can effectively suppress the devitrification of the glass even when the content of Bi₂O₃ is 30% or more. Further, when CuO is added, laser absorption characteristics at the time of laser sealing can be improved. The content of CuO is preferably from 0% to 40%, from 5% to 35%, or from 10% to 30%, particularly preferably from 13% to 25%. When the content of CuO is too large, the glass composition loses its component balance, and hence the devitrification resistance is liable to lower contrarily. In addition, the total light transmittance of the sealing material layer excessively lowers.

Fe₂O₃ is a component which improves the devitrification resistance and the laser absorption characteristics, and the content of Fe₂O₃ is preferably from 0% to 10% or from 0.1% to 5%, particularly preferably from 0.4% to 2%. When the content of Fe₂O₃ is too large, the glass composition loses its component balance, and hence the devitrification resistance is liable to lower contrarily.

MnO is a component which improves the laser absorption characteristics. The content of MnO is preferably from 0% to 25% or from 0.1% to 20%, particularly preferably from 5% to 15%. When the content of MnO is too large, the devitrification resistance is liable to lower.

Sb₂O₃ is a component which improves the devitrification resistance, and the content of Sb₂O₃ is preferably from 0% to 5%, particularly preferably from 0% to 2%. When the content of Sb₂O₃ is too large, the glass composition loses its component balance, and hence the devitrification resistance is liable to lower contrarily.

The glass powder preferably has an average particle diameter D₅₀ of less than 15 μm or from 0.5 μm to 10 μm, particularly preferably from 0.8 μm to 5 μm. As the average particle diameter D₅₀ of the glass powder is smaller, the softening point of the glass powder lowers.

As the refractory filler powder, one kind or two or more kinds selected from cordierite, zircon, tin oxide, niobium oxide, zirconium phosphate-based ceramic, willemite, β-eucryptite, and β-quartz solid solution are preferably used, and β-eucryptite or cordierite is particularly preferred. Those refractory filler powders each have a low thermal expansion coefficient and a high mechanical strength, and besides are each well compatible with the bismuth-based glass.

The average particle diameter D₅₀ of the refractory filler powder is preferably less than 2 μm, particularly preferably less than 1.5 μm. When the average particle diameter D₅₀ of the refractory filler powder is less than 2 μm, the surface smoothness of the sealing material layer is improved, and the average thickness of the sealing material layer is easily controlled to less than 8 μm. As a result, the accuracy of the laser sealing can be improved.

The refractory filler powder has a 99% particle diameter D₉₉ of preferably less than 5 μm or 4 μm or less, particularly preferably 3 μm or less. When the 99% particle diameter D₉₉ of the refractory filler powder is less than 5 μm, the surface smoothness of the sealing material layer is improved, and the average thickness of the sealing material layer is easily controlled to less than 8 μm. As a result, the accuracy of the laser sealing can be improved. Herein, the “average particle diameter D₅₀” and the “99% particle diameter D₉₉” each refer to a value measured by laser diffractometry on a volume basis.

The sealing material layer may further comprise a laser absorber in order to improve light absorption characteristics. However, the laser absorber has actions of excessively improving the light absorption characteristics of the sealing material layer and accelerating the devitrification of the bismuth-based glass, and hence, the content of the laser absorber in the sealing material layer is preferably 10 vol % or less, 5 vol % or less, 1 vol % or less, or 0.5 vol % or less. It is particularly preferred that the sealing material layer be substantially free of the laser absorber. As the laser absorber, a Cu-based oxide, an Fe-based oxide, a Cr-based oxide, a Mn-based oxide, or a spinel-type composite oxide thereof may be used.

The thermal expansion coefficient of the sealing material layer is preferably from 55×10⁻⁷/° C. to 95×10⁻⁷/° C. or from 60×10⁻⁷/° C. to 82×10⁻⁷/° C., particularly preferably from 65×10⁻⁷/° C. to 76×10⁻⁷/° C. With this, the thermal expansion coefficient of the sealing material layer matches the thermal expansion coefficients of the glass cover and the ceramic base, and hence a stress remaining in the sealed sites is reduced. The “thermal expansion coefficient” refers to a value measured with a push-rod type thermal expansion coefficient measurement (TMA) apparatus in a temperature range of from 30° C. to 300° C.

In the method of producing a hermetic package of the present invention, the sealing material layer is preferably formed by applying and sintering a composite powder paste. With this, the dimensional accuracy of the sealing material layer can be improved. In this case, the composite powder paste is a mixture of the composite powder and a vehicle. In addition, the vehicle generally comprises a solvent and a resin. The resin is added for the purpose of adjusting the viscosity of the paste. In addition, a surfactant, a thickener, or the like may also be added thereto as required. The produced composite powder paste is applied onto a surface of the glass cover by means of a coating machine, such as a dispenser or a screen printing machine.

The composite powder paste is preferably applied in a frame shape along a peripheral end edge region of the glass cover. With this, an area through which light radiated from a light emitting device or the like is extracted to an outside can be increased.

The composite powder paste is generally produced by kneading the composite powder and the vehicle with a triple roller or the like. The vehicle generally contains a resin and a solvent. As the resin to be used in the vehicle, there may be used an acrylic acid ester (acrylic resin), ethylcellulose, a polyethylene glycol derivative, nitrocellulose, polymethylstyrene, polyethylene carbonate, polypropylene carbonate, a methacrylic acid ester, and the like. As the solvent to be used in the vehicle, there may be used N,N′-dimethyl formamide (DMF), α-terpineol, a higher alcohol, γ-butyrolactone (γ-BL), tetralin, butylcarbitol acetate, ethyl acetate, isoamyl acetate, diethylene glycol monoethyl ether, diethylene glycol monoethyl ether acetate, benzyl alcohol, toluene, 3-methoxy-3-methylbutanol, triethylene glycol monomethyl ether, triethylene glycol dimethyl ether, dipropylene glycol monomethyl ether, dipropylene glycol monobutyl ether, tripropylene glycol monomethyl ether, tripropylene glycol monobutyl ether, propylene carbonate, dimethyl sulfoxide (DMSO), N-methyl-2-pyrrolidone, and the like.

Various glasses may be used as the glass cover. For example, alkali-free glass, borosilicate glass, or soda lime glass may be used. In particular, in order to increase a total light transmittance in an ultraviolet wavelength region, a low-iron-containing glass cover (having a content of Fe₂O₃ of 0.015 mass % or less, particularly less than 0.010 mass % in a glass composition) is preferably used.

The thickness of the glass cover is preferably from 0.01 mm to 2.0 mm or from 0.1 mm to 1 mm, particularly preferably from 0.2 mm to 0.7 mm. With this, thinning of the hermetic package can be achieved. In addition, the total light transmittance in the ultraviolet wavelength region can be increased.

A difference in thermal expansion coefficient between the sealing material layer and the glass cover is preferably less than 55×10⁻⁷/° C., particularly preferably 25×10⁻⁷/° C. or less. When the difference in thermal expansion coefficient is too large, a stress remaining in the sealed sites is improperly increased, and the hermetic reliability of the hermetic package is liable to be reduced.

The method of producing a hermetic package of the present invention comprises a step of irradiating the sealing material layer with laser light from a glass cover side to soften and deform the sealing material layer, to thereby hermetically integrate the ceramic base and the glass cover with each other to obtain a hermetic package. In this case, the glass cover may be arranged below the ceramic base, but from the viewpoint of the efficiency of the laser sealing, the glass cover is preferably arranged above the ceramic base.

Various lasers may be used as the laser. In particular, a semiconductor laser, a YAG laser, a CO₂ laser, an excimer laser, and an infrared laser are preferred because those lasers are easy to handle.

An atmosphere for performing the laser sealing is not particularly limited. An air atmosphere or an inert atmosphere, such as a nitrogen atmosphere, may be adopted.

At the time of laser sealing, when the glass cover is preheated at a temperature higher than or equal to 100° C. and lower than or equal to the temperature limit of the light emitting device or the like in the ceramic base, the breakage of the glass cover owing to thermal shock can be suppressed. In addition, when an annealing laser is radiated from the glass cover side immediately after the laser sealing, the breakage of the glass cover owing to thermal shock can be suppressed.

The laser sealing is preferably performed under a state in which the glass cover is pressed. With this, the sealing material layer can be softened and deformed acceleratedly at the time of laser sealing.

A hermetic package of the present invention is a hermetic package, comprising a ceramic base and a glass cover hermetically integrated with each other through intermediation of a sealing material layer, in which the sealing material layer has a total light transmittance in a thickness direction at a wavelength of 808 nm of 10% or more and 80% or less. The technical features of the hermetic package of the present invention have already been described in the description section of the method of producing a hermetic package of the present invention. Therefore, in this case, for convenience, the detailed description thereof is omitted.

Now, the present invention is described with reference to the drawings. FIG. 2 is a conceptual sectional view for illustrating one embodiment of the present invention. A hermetic package (e.g., ultraviolet LED package) 1 comprises an aluminum nitride base 10 and a glass cover 11. The aluminum nitride base 10 comprises abase part 12, and further a frame part 13 on a peripheral end edge of the base part 12. In addition, an internal device (e.g., ultraviolet LED device) 14 is housed inside the frame part 13 of the aluminum nitride base 10. Moreover, the surface of a top 15 of the frame part 13 is subjected to polishing treatment in advance, and has a surface roughness Ra of 0.15 μm or less. Electrical wiring (not shown) configured to electrically connect the ultraviolet LED device 14 to an outside is formed in the aluminum nitride base 10.

A sealing material layer 16 is formed in a frame shape on the surface of the glass cover 11. The sealing material layer 16 contains bismuth-based glass and refractory filler powder, but is substantially free of a laser absorber. Moreover, the width of the sealing material layer 16 is slightly smaller than the width of the top 15 of the frame part 13 of the aluminum nitride base 10. Further, the average thickness of the sealing material layer 16 is set to less than 8.0 μm.

Laser light L output from a laser irradiation apparatus 17 is radiated from a glass cover 11 side along the sealing material layer 16. With this, the sealing material layer 16 softens and flows to react with a surface layer of the aluminum nitride base 10, to thereby hermetically integrate the aluminum nitride base 10 and the glass cover 11 with each other. Thus, a hermetic structure of the hermetic package 1 is formed.

### EXAMPLES

Now, the present invention is described in detail by way of Examples. The following Examples are merely illustrative. The present invention is by no means limited to the following Examples.

First, bismuth-based glass powder and refractory filler powder, and as required, a laser absorber were mixed at a ratio shown in Table 1. Thus, composite powder shown in Table 1 was produced. Herein, the bismuth-based glass powder had an average particle diameter D₅₀ of 1.0 μm and a 99% particle diameter D₉₉ of 2.5 μm. The refractory filler powder had an average particle diameter D₅₀ of 1.0 μm and a 99% particle diameter D₉₉ of 2.5 μm. As the laser absorber, a Mn—Fe-based composite oxide or a Mn—Fe—Al-based composite oxide was used. Those composite oxides each had an average particle diameter D₅₀ of 1.0 μm and a 99% particle diameter D₉₉ of 2.5 μm.

TABLE 1

| | | No. 1 | No. 2 | No. 3 | No. 4 | No. 5 |
|---|---|---|---|---|---|---|
| Bismuth-based | Bi₂O₃ | 38.9 | 36.9 | 41.8 | 38.9 | 41.8 |
| glass | B₂O₃ | 23.7 | 26.9 | 26.8 | 23.7 | 26.8 |
| mol (%) | ZnO | 14.1 | 8.9 | 13.3 | 14.1 | 13.3 |
| | Al₂O₃ | 2.7 | 1.1 | 2.4 | 2.7 | 2.4 |
| | CuO | 20.1 | 25.5 | 15.1 | 20.1 | 15.1. |
| | Fe₂O₂ | 0.6 | 0.7 | 0.8 | 0.6 | 0.8 |

| | | | | | |
|---|---|---|---|---|---|
| Refractory Filler | β-eucryptite | Cordierite | β-eucryptite | β-eucryptite | Cordierite |
| Laser absorber | — | — | — | Mn—Fe-based | Mn—Fe—Al-based |
| Mixing ratio (vol %) | 73/27/0 | 73/27/0 | 73/27/0 | 68/25.7/6.3 | 72/25/3 |
| Glass/filler/absorber | | | | | |
| Total light | 21 | 15 | 30 | 3 | 9 |
| transmittance (%) | | | | | |
| 808 nm | | | | | |
| Thermal expansion | 70 | 74 | 76 | 72 | 80 |
| coefficient | | | | | |
| (×10⁻⁷/° C.) | | | | | |
| Sealing strength | ∘ | ∘ | ∘ | x | x |
| Hermetic reliability | ∘ | ∘ | ∘ | x | x |

The resultant composite powder was measured for a thermal expansion coefficient. The result is shown in Table 1. The thermal expansion coefficient refers to a value measured with a push-rod-type TMA apparatus in a measurement temperature range of from 30° C. to 300° C.

Next, a sealing material layer in a frame shape was formed on the peripheral end edge of a glass cover (measuring 3 mm in length×3 mm in width×0.2 mm in thickness, an alkali borosilicate glass substrate, thermal expansion coefficient: 66×10⁻⁷/° C.) through use of the composite powder. Specifically, first, the composite powder shown in Table 1, a vehicle, and a solvent were kneaded so as to achieve a viscosity of about 100 Pa·s (25° C., shear rate: 4), and then further kneaded with a triple roll mill until powders were homogeneously dispersed, and formed into a paste. Thus, a composite powder paste was obtained. A vehicle obtained by dissolving an ethyl cellulose resin in a glycol ether-based solvent was used as the vehicle. Next, the resultant composite powder paste was printed in a frame shape with a screen printing machine along the peripheral end edge of the glass cover. Further, the composite powder paste was dried at 120° C. for 10 minutes under an air atmosphere, and then fired at 500° C. for 10 minutes under an air atmosphere. Thus, a sealing material layer having a thickness of 5.0 μm and a width of 200 μm was formed on the glass cover. The resultant sealing material layer was measured for a total light transmittance in a thickness direction with a spectrophotometer (U-4100 spectrophotometer manufactured by Hitachi High-Technologies Corporation). The result is shown in Table 1.

In addition, an aluminum nitride base (measuring 3 mm in length×3 mm in width×0.7 mm in thickness of a base part, thermal expansion coefficient: 46×10⁻⁷/° C.) was prepared, and a deep ultraviolet LED device was housed inside a frame part of the aluminum nitride base. The frame part has a frame shape having a width of 600 μm and a height of 400 μm, and is formed along the peripheral end edge of the base part of the aluminum nitride base.

Finally, the aluminum nitride base and the glass cover were arranged so as to be laminated on each other so that a top of the frame part of the aluminum nitride base and the sealing material layer were brought into contact with each other. After that, a semiconductor laser at a wavelength of 808 nm and 12 W was radiated to the sealing material layer from a glass cover side to soften and deform the sealing material layer, to thereby hermetically integrate a sintered glass-containing layer and the sealing material layer with each other. Thus, a hermetic package (each of Sample Nos. 1 to 5) was obtained.

The sealing strength of the resultant hermetic package was evaluated. Specifically, the aluminum nitride base was separated from the resultant hermetic package, and then, the sealing material layer formed on the top of the frame part of the aluminum nitride base was removed, and a surface layer on the top of the frame part was visually observed. The sealing strength was evaluated as follows: a case in which a reaction mark was observed was indicated by Symbol “o”; and a case in which a reaction mark was not observed was indicated by Symbol “x”.

The hermetic reliability of the resultant hermetic package was evaluated. Specifically, the resultant hermetic package was subjected to a pressure cooker test (highly accelerated temperature and humidity stress test: HAST test), and then, the neighborhood of the sealing material layer was observed. The hermetic reliability was evaluated as follows: a case in which transformation, cracks, peeling, and the like were not observed at all was indicated by Symbol “o”; and a case in which transformation, cracks, peeling, and the like were observed was indicated by Symbol “x”. The conditions of the HAST test are 121° C., a humidity of 100%, 2 atm, and 24 hours.

As apparent from Table 1, the hermetic packages according to Sample Nos. 1 to 3, in each of which the total light transmittance of the sealing material layer in the thickness direction was controlled to fall within a predetermined range, received satisfactory evaluations for the sealing strength and the hermetic reliability. The hermetic packages according to Sample Nos. 4 and 5, in each of which the total light transmittance of the sealing material layer in the thickness direction was too low, received unsatisfactory evaluations for the sealing strength and the hermetic reliability.

### INDUSTRIAL APPLICABILITY

The hermetic package of the present invention is suitable for a hermetic package having mounted therein an ultraviolet LED device. Other than the above, the hermetic package of the present invention is also suitably applicable to a hermetic package having mounted therein, for example, a sensor device, a piezoelectric vibration device, or a wavelength conversion device in which quantum dots are dispersed in a resin.

### REFERENCE SIGNS LIST

1 hermetic package
10 aluminum nitride base
11 glass cover
12 base part
13 frame part
14 internal device
15 top of frame part
16 sealing material layer
17 laser irradiation apparatus
L laser light

1. A method of producing a hermetic package, comprising the steps of:
preparing a ceramic base;
preparing a glass cover;
forming, on the glass cover, a sealing material layer having a total light transmittance in a thickness direction at a wavelength of laser light to be radiated of 10% or more and 80% or less;
arranging the glass cover and the ceramic base so that the glass cover and the ceramic base are laminated on each other through intermediation of the sealing material layer; and
irradiating the sealing material layer with the laser light from a glass cover side to soften and deform the sealing material layer, to thereby hermetically integrate the ceramic base and the glass cover with each other to obtain a hermetic package.

2. A method of producing a hermetic package, comprising the steps of:
preparing a ceramic base;
preparing a glass cover;
forming, on the glass cover, a sealing material layer having a total light transmittance in a thickness direction at a wavelength of 808 nm of 10% or more and 80% or less;
arranging the glass cover and the ceramic base so that the glass cover and the ceramic base are laminated on each other through intermediation of the sealing material layer; and
irradiating the sealing material layer with laser light from a glass cover side to soften and deform the sealing material layer, to thereby hermetically integrate the ceramic base and the glass cover with each other to obtain a hermetic package.

3. The method of producing a hermetic package according to claim 1, wherein the step of forming a sealing material layer is performed so that the sealing material layer has an average thickness of less than 8.0 μm.

4. The method of producing a hermetic package according to claim 1, wherein the step of forming a sealing material layer comprises firing composite powder containing at least bismuth-based glass powder and refractory filler powder to form the sealing material layer on the glass cover.

5. The method of producing a hermetic package according to claim 1, wherein the ceramic base to be used comprises a base part and a frame part formed on the base part.

6. The method of producing a hermetic package according to claim 1, wherein the ceramic base has a property of absorbing the laser light to be radiated.

7. A method of producing a hermetic package, comprising the steps of:
preparing a ceramic base having dispersed therein a black pigment;
preparing a glass cover;
forming, on the glass cover, a sealing material layer having a total light transmittance in a thickness direction at a wavelength of laser light to be radiated of 10% or more and 80% or less;
arranging the glass cover and the ceramic base so that the glass cover and the ceramic base are laminated on each other through intermediation of the sealing material layer; and
irradiating the sealing material layer with the laser light from a glass cover side to soften and deform the sealing material layer and heat the ceramic base, to thereby hermetically integrate the ceramic base and the glass cover with each other to obtain a hermetic package.

8. A hermetic package, comprising a ceramic base and a glass cover hermetically integrated with each other through intermediation of a sealing material layer,
wherein the sealing material layer has a total light transmittance in a thickness direction at a wavelength of 808 nm of 10% or more and 80% or less.

9. The hermetic package according to claim 8, wherein the sealing material layer has an average thickness of less than 8.0 μm.

10. The hermetic package according to claim 8, wherein the sealing material layer comprises a sintered body of composite powder containing at least bismuth-based glass powder and refractory filler powder.

11. The hermetic package according to claim 8, wherein the sealing material layer is substantially free of a laser absorber.

12. The hermetic package according to claim 8, wherein the ceramic base comprises a base part and a frame part formed on the base part.

13. The hermetic package according to claim 8, wherein the ceramic base has a thermal conductivity of 1 W/(m·K) or more.

14. The hermetic package according to claim 8, wherein the ceramic base comprises any one of glass ceramic, aluminum nitride, and alumina, or a composite material thereof.

15. The hermetic package according to claim 8, wherein the hermetic package has housed therein any one of an ultraviolet LED device, a sensor device, a piezoelectric vibration device, and a wavelength conversion device in which quantum dots are dispersed in a resin.
